(19) United States
(12) Patent Application Publication
(10) Pub. No.: US 2011/0248756 A1
(43) Pub. Date: Oct. 13, 2011

(54) SEMICONDUCTOR CIRCUIT

(75) Inventor: Tsuneo ABE, Tokyo (JP)

(73) Assignee: ELPIDA MEMORY, INC., Tokyo (JP)

(21) Appl. No.: 13/084,071

(22) Filed: Apr. 11, 2011

(30) Foreign Application Priority Data
Apr. 13, 2010 (JP) 2010-092087

(51) Int. Cl. H03L 7/06

(52) U.S. Cl. 327/158

(57) ABSTRACT

Power consumption in a DLL circuit having a DCC circuit is reduced. Specifically, a semiconductor circuit includes a change-in-duty detection circuit, activation and deactivation of which is controlled based upon a control signal (DCCEN), for comparing duty of a clock signal that has been generated based upon an input clock signal and a preset duty and outputting result of the comparison; and a duty determination circuit for outputting the control signal (DCCEN) for deactivating the change-in-duty detection circuit when the output of the change-in-duty detection circuit indicates that duty of the generated clock signal is in the vicinity of a target value, which is a preset duty, and outputting the control signal (DCCEN) for activating the change-in-duty detection circuit when the duty of the generated clock signal is not in the vicinity of the target value.

### TECHNICAL FIELD

### Reference to Related Application

This application is based upon and claims the benefit of the priority of Japanese patent application No. 2010-092087, filed on Apr. 13, 2010, the disclosure of which is incorporated herein in its entirety by reference thereto. This invention relates to a semiconductor circuit and, more particularly, to a semiconductor circuit having a DLL (Delay-Locked Loop) circuit.

### BACKGROUND

A DLL circuit has a delay line the delay time of which is variably controlled, a phase detector for comparing the output signal of the delay line and an input signal to the delay line, and a counter for counting up or counting down based upon the result of the phase comparison performed by the phase detector, wherein the delay time of the delay line is adjusted based upon the count value in the counter (or the result of decoding the count value) to thereby synchronize the output from the delay line with the input signal. A known example of such a DLL circuit includes a variable delay line capable of setting delay time relatively at a coarse delay resolution (delay unit), and a synthesizing circuit [referred to also as an “interpolating circuit (interpolator)”] for generating a delay signal, the resolution of which is higher than the delay unit of the variable delay line, by synthesizing, at a set ratio, a phase difference (delay) between two signals having different delay times generated by the variable delay line, whereby the circuit performs a coarse adjustment of delay by the variable delay line and a fine adjustment of delay by the synthesizing circuit. The synthesizing circuit (interpolator), which internally divides the delays of the two signals and outputs a signal having an intermediate delay, includes a precharge circuit for precharging a prescribed node to a predetermined voltage, and first and second discharge elements, which are turned on in a period of time in which the first and second input signals, respectively, are at the high level, for discharging the precharged node at current values xI, (1-x)I conforming to an internal dividing ratio x:(1-x) (where 0≦x≦1 holds).

The operating frequency of semiconductor circuits has been raised remarkably in recent years, and a problem which arises in a DLL circuit that controls the delay of a high-speed clock is a deviation in clock duty, etc. Accordingly, the present inventor has devised a DLL circuit that makes it possible to avoid erroneous operation of a synthesizing circuit and support an increase in operating frequency in a case where clock pulse width is narrow and in a case where it is wide as well (see Patent Document 2). At the input stage of a synthesizing circuit (interpolator) for combining, at a fixed ratio, two delayed signals of different delay times that are output from a variable delay line, the DLL circuit includes a circuit for generating a one-shot pulse in response to prescribed transitions of the delay signals, and a latch circuit that is set upon receiving a one-shot pulse and reset based upon an output from the synthesizing circuit (interpolator), wherein an output signal of the latch circuit when the latch circuit is set is input to the synthesizing circuit (interpolator).

Further, Patent Document 2 discloses a DLL circuit capable of performing a duty-cycle correcting operation and reducing power consumption which becomes a problem at high-speed operation. This DLL circuit includes a buffer for receiving an external clock signal and outputting a clock input signal; a delay line unit, which receives the clock input signal and first and second comparison signals, for generating first and second clock signals obtained by delaying the clock input signal by a prescribed length of time; a phase detector for receiving inverted signals of the first and second clock signals and generating a phase detection signal indicating which of the falling edges of the first and second clock signals is earlier; a mixing control unit for deciding whether the DLL is locked based upon the first and second comparison signals and outputting an on/off signal depending upon whether the DLL is locked; a first signal processor for receiving the first and second clock signals, generating a first compensation clock signal based upon these clock signals, receiving the external clock signal and comparing this signal with the first compensation signal and generating the first comparison signal; and a second signal processor for receiving the first and second clock signals, generating a second compensation clock signal based upon these clock signals, receiving the external clock signal and comparing this signal with the second compensation signal, generating the second comparison signal and being activated or deactivated depending upon the on/off signal.
[Patent Document 1]
Japanese Patent Kokai Publication No. JP2010-62937A, which corresponds to U.S. Pat. No. 7,830,189B2.
[Patent Document 2]
Japanese Patent Kokai Publication No. JP2004-328721A, which corresponds to U.S. Pat. No. 6,956,418B2.

### SUMMARY

The entire disclosure of the above-mentioned Patent Documents are incorporated herein by reference thereto. The analysis set forth below is given in the present invention.

In a DRAM or the like, a DLL circuit used as a clock generating circuit generates a clock signal having a desired phase by exercising control to vary the amount of delay of an external clock signal (CK below) input thereto. There are cases where such a DLL circuit is equipped with a DCC (Duty Cycle Corrector) function. The DCC function is a function for producing and outputting a waveform having a set duty, e.g., 50%, irrespective of the duty (the proportion of high-level period of time in one cycle, also referred to as the “duty ratio”) of the applied external clock signal CK.

The DCC function manifests its effectiveness in a case where the duty of the applied external clock signal CK has deviated from the desired duty, i.e., in a case where duty of the external clock signal has deteriorated. However, in a case where the duty of the external clock signal CK has not deteriorated, i.e., in a case where the duty of the signal CK is the desired duty, e.g., 50%, the DLL circuit is capable of producing the waveform having the duty of 50% even without using the DCC function.

In the case where the DCC function is being used, the circuit block that implements this function operates and, as a consequence, several milliamperes of current consumption occurs in accordance with such operation. These several milliamperes of consumed current make up a major proportion of current consumption when the device is in a consumed-current save condition, such as a powered-down condition.

Conventionally, however, whether the DCC function is used or not is fixedly set as by a metal fuse or the like and therefore whether the function is used or not is decided irrespective of the actual duty of the external clock signal CK. Accordingly, even if the actual duty of the external clock signal CK is the desired duty, the DCC function is used needlessly if use of the DCC function has been set, and the problem which arises is a wasteful increase in power consumption. Conversely, when an external clock signal CK whose duty has deteriorated is input in a case where use of the DCC function has not been set, naturally the DCC function cannot be activated. Consequently, the problem which arises is that the circuit which receives the output clock signal from the DLL circuit will not operate normally. Thus there is much desired in the art.

According to a first aspect of the present invention there is provided a semiconductor circuit which comprises: a DLL circuit for generating and outputting an output clock signal obtained by delaying an external clock signal that has been input thereto; and a change-in-duty detection circuit, activation and deactivation of which is controlled based upon a control signal, for comparing duty of a clock signal that has been generated based upon the output clock signal and a preset duty and outputting result of the comparison as a change-in-duty signal. A duty determination circuit outputs the control signal for deactivating the change-in-duty detection circuit when the change-in-duty signal indicates that the duty of the output clock signal is in the vicinity of a target value, which is a preset duty, and outputs the control signal for activating the change-in-duty detection circuit when the change-in-duty signal indicates that the duty of the output clock signal is not in the vicinity of a target value, which is a preset duty.

In accordance with the present invention, the change-in-duty detection circuit, which compares the duty of the output clock signal with the target duty and outputs the result of the comparison, is deactivated in a case where the duty of the output clock signal is the same as or near the target duty, and is activated in a case where the duty of the output clock signal has deviated from the target value. As a result, it is possible for the change-in-duty detection circuit to be activated and deactivated dynamically in conformity with the duty of the external clock signal, thereby enabling a reduction in power consumption in a case where the duty is near the target value and enabling correction of duty in a case where the duty has deviated from the target value. Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a block diagram illustrating the configuration of a DLL circuit according to an exemplary embodiment of the present invention;

FIG. 2 is a timing chart representing operation of a duty determination circuit;

FIG. 3 is a timing chart representing operation of a duty determination circuit in a case where duty is approximately at 50%;

FIG. 4 is a timing chart representing operation of a duty determination circuit in a case where duty falls below 50%; and

FIG. 5 is a timing chart representing operation of a duty determination circuit in a case where duty exceeds 50%.

### PREFERRED MODES

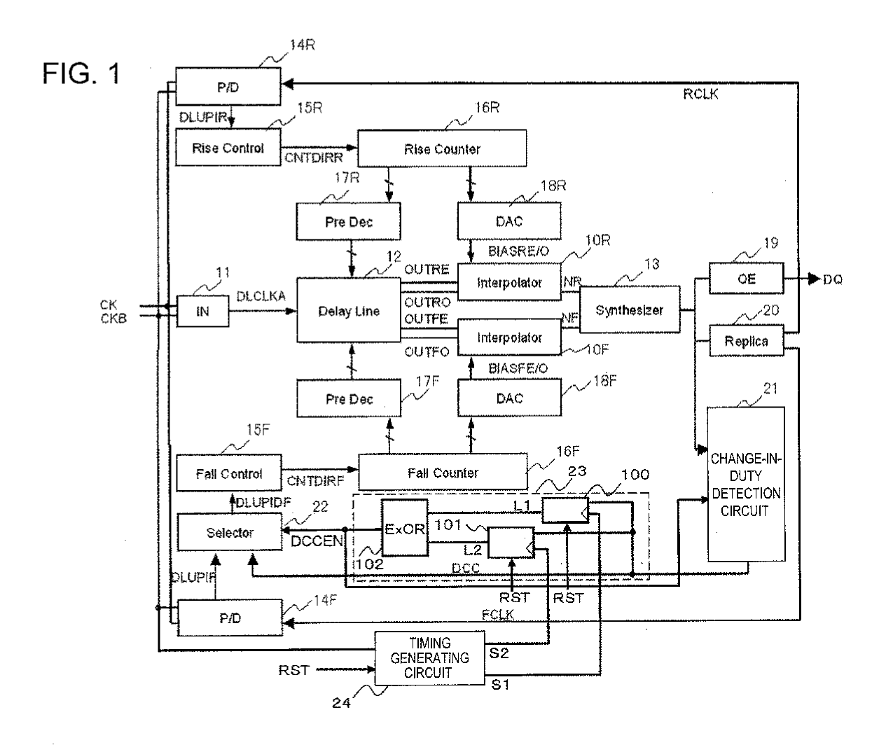

A semiconductor circuit according to an exemplary embodiment of the present invention comprises: a DLL circuit for generating and outputting an output clock signal obtained by delaying an external clock signal that has been input thereto; a change-in-duty detection circuit 21 (FIG. 1), activation and deactivation of which is controlled based upon a control signal, for comparing duty of a clock signal that has been generated based upon the output clock signal and a preset duty and outputting result of the comparison as a change-in-duty signal; and a duty determination circuit 23 (1) for outputting the control signal for deactivating the change-in-duty detection circuit when the change-in-duty signal indicates that the duty of the output clock signal is in the vicinity of a target value, which is a preset duty, and outputting the control signal for activating the change-in-duty detection circuit when the change-in-duty signal indicates that the duty of the output clock signal is not in the vicinity of a target value, which is a preset duty.

More specifically, the duty determination circuit compares the present output of the change-in-duty detection circuit with the output thereof at the immediately preceding timing and determines that duty is in the vicinity of the target value when the target value is bracketed, i.e., if one of these outputs is smaller than the target value and the other is greater than the target value.

More specifically, the DLL circuit outputs the output clock signal having the target duty ratio by adjusting the temporal position of one edge of the generated output clock signal in accordance with whether the one edge of the output clock signal temporally leads or lags behind one edge of the applied external clock signal, and adjusting the temporal position of another edge of the output clock signal in accordance with whether this other edge of the output clock signal temporally leads or lags behind another edge of the applied external clock signal. The DLL circuit includes a change-in-duty detection circuit 21 (FIG. 1) for comparing duty ratio of the output clock signal and a target duty ratio and outputting a change-in-duty signal indicating which duty ratio is larger; a duty determination circuit 23 (FIG. 1) for outputting a comparison-result signal representing whether the change-in-duty signal at a plurality of different timings is the same; and a selection circuit 22 (FIG. 1) which, in order to adjust the temporal position of the one edge of the output clock signal, selects result of a phase comparison between the external clock signal and the output clock signal in a case where the comparison-result signal indicates that the change-in-duty signal is not the same, and selects the change-in-duty signal in a case where the comparison-result signal indicates that the change-in-duty signal is the same. The change-in-duty detection circuit is deactivated in a case where the comparison-result signal indicates that the change-in-duty signal is not the same, and is activated in a case where the comparison-result signal indicates that the change-in-duty signal is the same. Note that the reference symbols mentioned hereinabove in the description of the preferred modes are intended non-restrictive to the drawings, and those reference symbols are presented merely for better illustration by way example.

As set forth above, the change-in-duty detection circuit, which compares the duty of the output clock signal generated based upon the applied external clock signal with the target duty and outputs the result of the comparison, is deactivated if the duty of the generated clock signal is the same as or near the target duty, and is activated if the duty of the generated clock signal has deviated from the target value. As a result, it is possible for the change-in-duty detection circuit to be activated and deactivated in conformity with the duty of the generated external clock signal, thereby enabling a reduction in power consumption in a case where the duty is near the target value and enabling correction of duty in a case where the duty has deviated from the target value.

More specifically, the change-in-duty detection circuit is deactivated in a case where the comparison-result signal indicates that the change-in-duty signal is not the same. That is, if the duty ratio of the output clock signal and the target duty ratio reverse in size with the passage of time, it is judged that the duty ratio of the output clock signal and the target duty ratio substantially agree and, hence, the change-in-duty detection circuit is deactivated. When the change-in-duty detection circuit is deactivated, a further reduction in power consumption can be achieved.

An exemplary embodiment of the present invention will now be described in greater detail with reference to the drawings.

### First Exemplary Embodiment

FIG. 1 is a block diagram illustrating the configuration of a DLL circuit according to a preferred exemplary embodiment of the present invention. As shown in FIG. 1, the DLL circuit includes: an input circuit (IN) 11; a variable delay line (Delay Line) 12; variable delay lines (Interpolator) 10R, 10F; a synthesizing circuit 13; phase detectors (P/D) 14R, 14F; a rise delay control circuit (Rise Control) 15R; a fall delay control circuit (Fall Control) 15F; a rise counter (Rise Counter) 16R; a fall counter (Fall Counter) 16F; predecoders (Pre Dec) 17R, 17F; digital/analog converters (DAC) 18R, 18F; an output circuit (OE) 19; a replica circuit (Replica) 20; a change-in-duty detection circuit 21; a selection circuit (Selector) 22; a duty determination circuit 23; and a timing generating circuit 24. The duty determination circuit 23 has latch circuits 100, 101 and an exclusive-OR gate 102.

Mutually complementary external clock signals CK, CKB are input to the input circuit (IN) 11, which proceeds to output a clock signal DLCLKA, which is in phase with the clock signal CK, to the variable delay line 12 in single-ended fashion.

The variable delay line 12 receives results of decoding from the predecoders 17R, 17F and decides the amount of delay of successively connected delay elements (Delay Line). The variable delay line 12 generates even-numbered (Even) and odd-numbered (Odd) signals OUTRE, OUTRO, respectively, in conformity with the rising edge (Rise) of the clock signal DLCLKA, and generates even-numbered (Even) and odd-numbered (Odd) signals OUTFE, OUTFO, respectively, in conformity with the falling edge (Fall) of the clock signal DLCLKA. The variable delay line 12 performs a delay adjustment using the Even/Odd time difference as a minimum delay unit. The Even/Odd time difference corresponds to two stages (unit delay) of a NAND gate, by way of example.

The delay signals OUTRE, OUTRO of Even and Odd, which have been generated from the rising-edge transition of the external clock signal CK, are input to the delay line 10R, which combines the signals OUTRE, OUTRO in accordance with bias voltages BIASRE, BIASRO. Specifically, the delay line 10R outputs a signal that rises at a delay obtained by interpolating a delay (phase difference) between rising edges of the delay signals OUTRE, OUTRO of Even and Odd at a ratio defined by the bias voltages BIASRE, BIASRO. For example, if the Even side is 100% and the Odd side is 0%, the delay line 10R synthesizes a waveform assuming OUTRE=100%, OUTRO=0% and generates an output signal NR. That is, this is output as transition timing of OUTRE=transition timing of NR (excluding intrinsic delay at passage through the circuit). If the Even side is 50% and the Odd side is 50%, the delay line 10R synthesizes a waveform assuming OUTRE=50%, OUTRO=50% of the input signal. Therefore, the signal is output at a timing that is intermediate the transition of OUTRE and the transition of OUTRO [(intermediate value of transition timings of OUTRE and OUTRO)+(intrinsic delay at passage through circuit)].

The delay signals OUTFE, OUTFO of Even and Odd, which have been generated from the falling-edge transition of the external clock signal CK, are input to the delay line 10F, which combines the signals OUTFE, OUTFO in accordance with bias voltages BIASFE, BIASFO. Specifically, the delay line 10F outputs a signal that falls at a delay obtained by interpolating a delay (phase difference) between falling edges of the delay signals OUTFE, OUTFO of Even and Odd at a ratio defined by the bias voltages BIASFE, BIASFO. It may be so arranged that the output signal from the delay line 10F rises to the high level in response to OUTFE, OUTFO falling to the low level. In this case, by adopting an arrangement in which inverted signals of OUTFE, OUTFO are input to the delay line 10F, the delay line 10F will have the same construction as that of the delay line 10R.

It is possible to adjust delay at a temporal resolution finer that the minimum delay unit of the variable delay line 12 (e.g., absolute delay-time value of two NAND stages) by the delay lines 10R, 10F, and it is possible to support a high-speed operating frequency while assuring the required temporal resolution and precision.

The synthesizing circuit (Synthesizer) 13 receives the output signal NR from the delay line 10R corresponding to the rise transition of the external clock signal CK and the output signal NF from the delay line 10F corresponding to the fall transition of the external clock signal CK, and generates a delayed clock signal, which is an output signal that rises in conformity with the rise transition of the output signal NR and falls in conformity with the fall transition of the output signal NF. It should be noted that the synthesizing circuit 13 is constituted by a circuit equivalent to ordinary flip-flops of two inverter stages whose inputs and outputs are mutually connected.

The replica circuit 20 that receives the delayed clock signal is constituted by a circuit equivalent to the delay of the actual signal route from the output of the synthesizing circuit 13 to the output terminal. The replica circuit 20 outputs a rise-side clock signal RCLK in phase with the external clock signal CK and a fall-side clock signal FCLK in phase with CKB (opposite in phase to RCLK).

The output circuit 19 outputs readout data serially from output terminal DQ in synch with the rise and fall of the delayed clock signal supplied from the synthesizing circuit 13. By way of example, the output circuit 19 comprises a multiplexer to which two items of readout data are input in parallel, the inputs being output selectively to output terminal DQ in accordance with the delayed clock signal.

The change-in-duty detection circuit 21 receives the delayed clock signal, which is the output of the synthesizing circuit 13, generates a change-in-duty signal DCC, which is information for changing duty, and outputs this signal to the selection circuit 22 and duty determination circuit 23. It should be noted that the change-in-duty detection circuit 21 has its activation controlled by a control signal (also referred to as a “DCC-enable signal” below) DCCEN. In a case where the control signal DCCEN is active, the change-in-duty detection circuit 21 ceases operating and attains a state in which it does not consume current. In this exemplary embodiment, the change-in-duty detection circuit 21 is set beforehand to 50% as a target duty, compares the size of the target duty of 50% and the size of the duty of the delayed clock signal that is output from the synthesizing circuit 13 and outputs the result of the comparison, as described above. Here it is noted that it is possible to set the target duty at will.

The duty determination circuit 23 determines whether the change-in-duty signal DCC at two different timings is information possessing the same size relationship with respect to the target duty and outputs the DCC-enable signal DCCEN, which is the result of the determination, to the selection circuit 22 and change-in-duty detection circuit 21.

The timing generating circuit 24 generates timing signals S1, S2 based upon the external clock signal CKB and a reset signal RST and supplies these timing signals to the duty determination circuit 23 after reset is performed.

Based upon the DCC-enable signal DCCEN, the selection circuit 22 selects either output DLUP1F of the phase detector 14F or the change-in-duty signal DCC, which is the output of the change-in-duty detection circuit 21, and supplies the selected signal to the fall delay control circuit 15F.

The phase detector (PD) 14R compares the phases of the rising edges of the external clock signal CK and clock signal RCLK, which is received from replica circuit 20. The rise delay control circuit 15R receives a phase-comparison result output DLUP1R from the phase detector 14R and outputs an up- or down-signal (CNTDIRR) to the rise counter 16R. Specifically, the rise delay control circuit 15R receives the result of the phase comparison by the phase detector 14R, generates the signal CNTDIRR to exercise control so as to advance the phase of the rising edge of RCLK if the phase of the rising edge of RCLK lags behind that of the signal CK or so as to retard the phase of the rising edge of RCLK if the phase of the rising edge of RCLK leads that of the signal CK, and supplies the signal CNTDIRR to the rise counter 16R to thereby control the counting operation thereof. The rise delay control circuit 15R comprises a buffer circuit (a non-inverting or an inverting buffer), although this does not impose any limitation.

Higher-order bits of the rise counter 16R are predecoded by the predecoder 17R and the result of decoding by the predecoder 17R is input to the variable delay line 12. Lower-order bits of the rise counter 16R are input to the digital/analog converter 18R, which generates the bias voltages BIASRE/BIASRO for even and odd numbers.

The phase detector (PD) 14F compares the phases of the falling edges of the external clock signal CK and output FCLK of replica circuit 20 and outputs the phase-comparison result DLUP1F to the selection circuit 22.

The fall delay control circuit 15F receives the output DLUP1DF of selection circuit 22 and outputs the up- or down-signal (CNTDIRR) to the fall counter 16F. For example, if the phase-comparison result DLUP1F is selected by the selection circuit 22, the fall delay control circuit 15F receives the result of the phase comparison by the phase detector 14F, generates the signal CNTDIRF to exercise control so as to advance the phase of the falling edge of FCLK if the phase of the falling edge of FCLK lags behind that of the signal CK or so as to retard the phase of the falling edge of FCLK if the phase of the falling edge of FCLK leads that of the signal CK, and supplies the signal CNTDIRF to the fall counter 16F to thereby control the counting operation thereof. The fall delay control circuit 15F comprises a buffer circuit (a non-inverting or an inverting buffer), although this does not impose any limitation.

Higher-order bits of the fall counter 16F are predecoded by the predecoder 17F and the result of decoding by the predecoder 17F is input to the variable delay line 12. Lower-order bits of the fall counter 16F are input to the digital/analog converter 18F, which generates the two bias voltages BIASRE/BIASRO.

The details of the duty determination circuit 23 will be described next. The latch circuits 100, 101 are reset by the reset signal RST and latch the change-in-duty signal DCC by timing signals S1, S2, respectively, which are output from the timing generating circuit 24. The exclusive-OR gate 102 obtains the exclusive-OR between output signals L1, L2 of the latch circuits 100, 101, respectively, generates the DCC-enable signal DCCEN and outputs this signal as selection information for the selection circuit 22 and activation information for the change-in-duty detection circuit 21.

Here it is assumed that the duty determination circuit 23 and timing generating circuit 24 start up before the DLL circuit starts. Start of the DLL circuit means that the phase of the delayed clock signal, which is output from the synthesizing circuit 13, is made to conform to the external clock signal CK using the phase detector 14R and the phase detector 14F or the change-in-duty detection circuit 21.

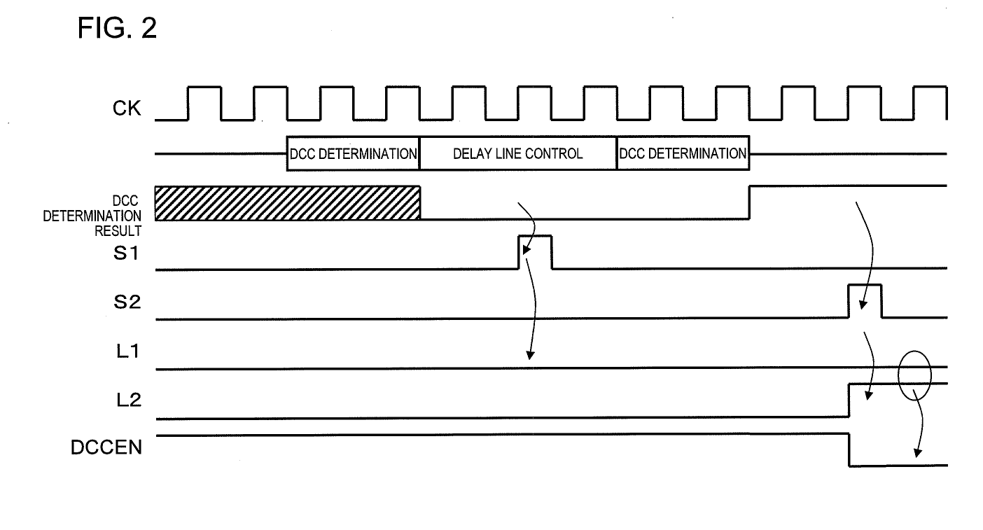

Next, a timing chart representing the operation of the duty determination circuit 23 will be described with reference to FIG. 2.

First, the duty determination circuit 23 is such that, after reset is achieved, the latch circuits 100 and 101 are reset by the reset signal RST and the output of the exclusive-OR gate 102, which receives the outputs of the latch circuits, attains the high level. The DCC-enable signal DCCEN, therefore, turns on (rises to the H level). Since the DCC-enable signal DCCEN is at the high level, the selection circuit 22 selects the change-in-duty signal DCC, which is the result that is output from the change-in-duty detection circuit 21, and supplies this signal to the fall delay control circuit 15F. The latch circuit 100 stores the change-in-duty signal DCC, which has been output from the change-in-duty detection circuit 21 in order to make the duty 50%, in response to the timing signal S1 (1^{st} latch signal). As a result, the change-in-duty signal DCC is reflected in the fall counter 16F by the side on which the change-in-duty detection circuit 21 has been added, namely by the fall delay control circuit 15F, and the delays of the variable delay lines 12, 10F are changed using the predecoder 17F and digital/analog converter 18F. As a result, with respect to the duty of the external clock signal CK, a clock signal obtained after a delay that reflects the result of updating the fall counter 16F one time is input to the change-in-duty detection circuit 21.

Next, in response to the timing signal S2 (2^{nd} latch signal), the latch circuit 101 latches change-in-duty signal DCC generated anew by the change-in-duty detection circuit 21 based upon the result of comparing the target duty of 50% with the duty of the delayed clock signal after the above-mentioned delay following updating of the fall counter 16F one time. This stored signal L2 and the signal L1 stored in the latch circuit 100 previously are input to the exclusive-OR gate 102 which, based upon the values of these inputs, outputs the DCC-enable signal DCCEN that controls the change-in-duty detection circuit 21 and selection circuit 22.

When the value that has been stored in the latch circuit 100, in which one of the inputs to the exclusive-OR gate 102 is the result of the first determination operation, is counter UP (e.g., the H level) and the value that has been stored in the latch circuit 101, in which the other input to the exclusive-OR gate 102 is the result of the second determination operation, is counter DOWN (e.g., the L level), the exclusive-OR gate 102 takes the exclusive-OR of these inputs and outputs the L level as the DCC-enable signal DCCEN.

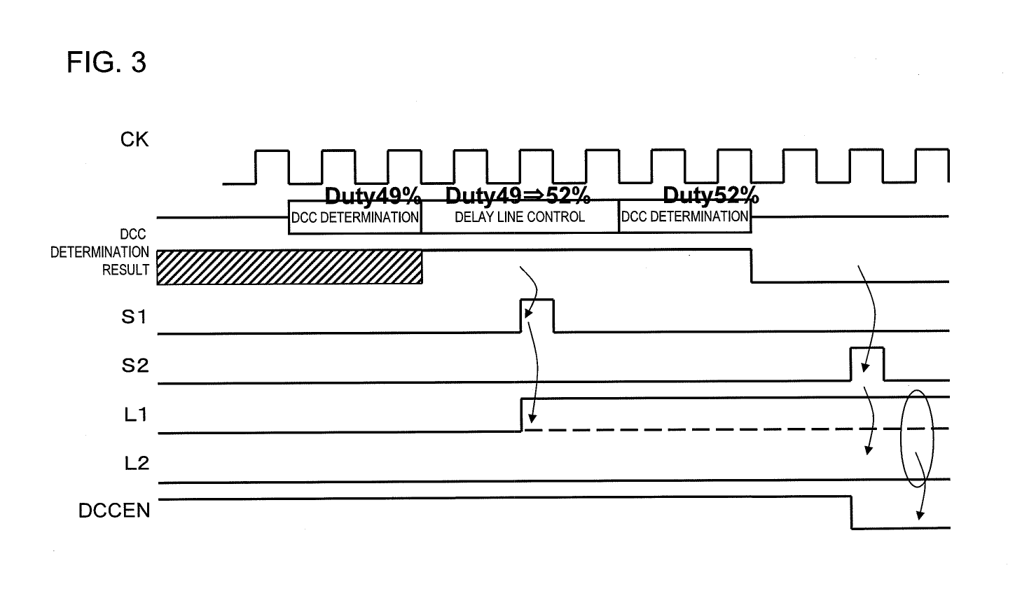

A concrete example will now be described. Assume that the DLL circuit is one in which duty is made to move by 3% by a single count of the counter. If the duty of the delayed clock signal after the delay is 49%, a shift of 3% in the direction of 100% will result in 52%. As a consequence, in the second determination, a determination is made conversely to reduce the duty. It is understood, therefore, that the duty of the delayed clock signal after the delay is present at a position that brackets the target value of 50%, and it is determined that the duty of the external clock signal CK that is the source of the delayed clock signal after the delay is approximately 50%. Even if the change-in-duty detection circuit 21 is deactivated, therefore, no problem arises and the duty determination circuit 23 places the DCC-enable signal DCCEN at the L level based upon the output of the exclusive-OR gate 102 (see FIG. 3).

On the other hand, in a case where the two inputs to the exclusive-OR gate 102, namely the output from the latch circuit 100 and the output from the latch circuit 101, are both at the L level or H level, the exclusive-OR gate 102 takes the exclusive-OR of these inputs and outputs the H level as the DCC-enable signal DCCEN.

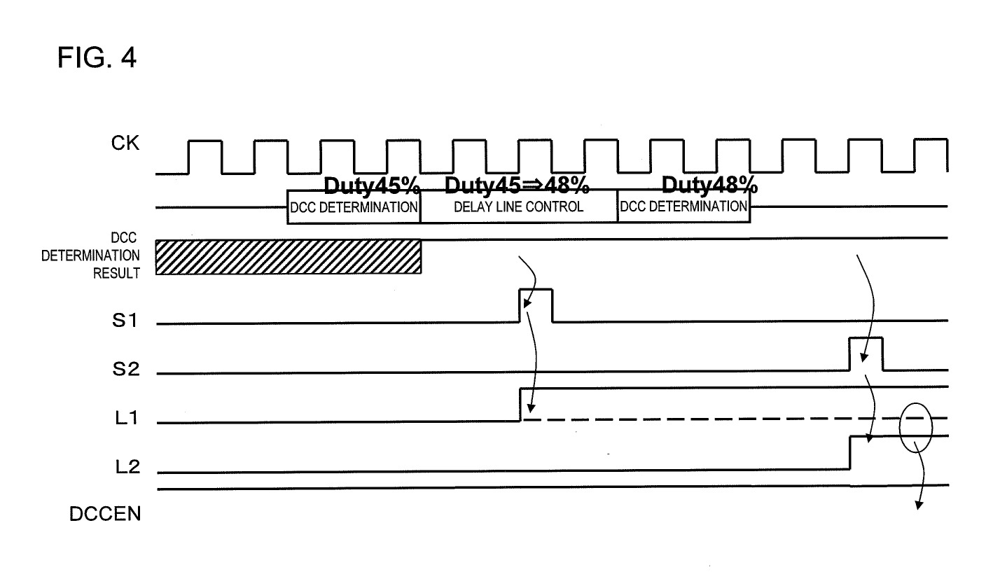

A concrete example will now be described. Assume that the duty of the delayed clock signal after the delay is 45%. Even if the duty is moved 3% based upon the result of the first determination, the result will be 48% and the duty will not exceed 50%. In this case, since the two determinations will be the same, it is determined that the duty of the external clock signal CK has deviated greatly from 50%. Accordingly, it is necessary to activate the change-in-duty detection circuit 21 and the duty determination circuit 23 places the DCC-enable signal DCCEN at the H level based upon the output of the exclusive-OR gate 102 (see FIG. 4).

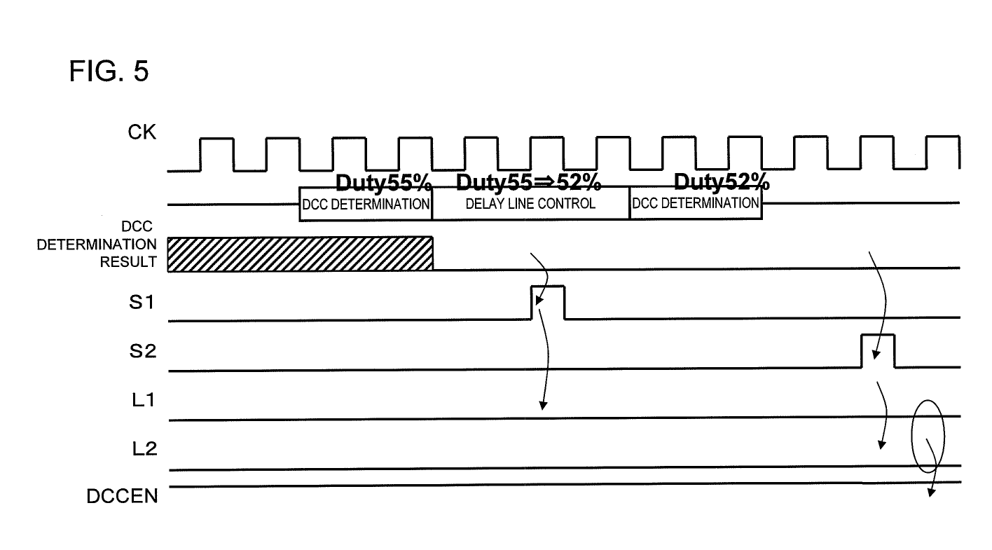

Similarly, assume that the duty of the delayed clock signal after the delay is 55%. Even if the duty is moved 3%, the result will be 52% and the duty will exceed 50%. In this case also the two determinations give the same value and it is determined that the duty of the external clock signal CK has deviated greatly from 50%. Accordingly, it is necessary to activate the change-in-duty detection circuit 21 and the duty determination circuit 23 places the DCC-enable signal DCCEN at the H level based upon the output of the exclusive-OR gate 102 (see FIG. 5).

In the foregoing description, the determination timing is a single time, namely “after the first DCC operation is reflected”. However, the determination timing is not limited to a single time. In order to determine whether the duty of the objective delayed clock signal after the delay is near 50%, a small number of determination timings is preferred. For example, in a case where duty moves only 1% by a single DCC operation, it is possible to perform this a plurality of times. On the other hand, in order to achieve higher accuracy, a single time will suffice. For example, in a case where duty moves only 1%, DCC=OFF holds only when the range of duties is 49 to 51%, and the effect of current reduction based upon DCC=OFF is narrowing of the range of supportable duties of the clock signal. However, the quality of the waveform (the duty precision) is improved. Conversely, if priority is given to current reduction, it is possible to widen the range of duties by even about ±5%.

Thus, as set forth above, in the DLL circuit of this exemplary embodiment, the change-in-duty detection circuit 21 is deactivated by supplying the L-level DCC-enable signal DCCEN in a case where it is indicated that the DCC-enable signal DCCEN is not the same at two timings. More specifically, in a case where the size relationship between the duty ratio of the delayed clock signal and the target duty ratio reverses with the passage of time, the duty determination circuit 23 judges that the duty ratio of the delayed clock signal and the target duty ratio substantially agree and outputs the L-level DCC-enable signal to thereby deactivate the change-in-duty detection circuit 21. By deactivating the change-in-duty detection circuit 21, power consumption is minimized.

Further, although the duty determination circuit 23 is provided anew in order to implement the function for automatically determining whether to use the phase detector 14F or the change-in-duty detection circuit 21, the duty determination circuit 23 is constituted by simple circuitry, namely by the latch circuits 100, 101 and exclusive-OR gate 102. Accordingly, the increase in scale of the circuitry and in power consumption relating to provision of this function is negligible in comparison with the reduction in power consumption that is the result of deactivating the change-in-duty detection circuit 21.

In this exemplary embodiment, it is described that the duty determination circuit is implemented by two latch circuits and an exclusive-OR gate. However, if the circuit is one which is capable of comparing the outputs of the change-in-duty detection circuit 21 at different timings and of determining whether duty is in the vicinity of a target value, then the circuit can be modified suitably as a matter of course.

In this exemplary embodiment, the target duty is described as being 50%. However, it is possible to set the duty at will as necessary.

The disclosures of the patent documents cited above are incorporated by reference in this specification. Within the bounds of the full disclosure of the present invention (inclusive of the scope of the claims), it is possible to modify and adjust the modes and exemplary embodiments of the invention based upon the fundamental technical idea of the invention. Multifarious combinations and selections of the various disclosed elements are possible within the bounds of the scope of the claims of the present invention. That is, it goes without saying that the invention covers various modifications and changes that would be obvious to those skilled in the art within the scope of the claims.

What is claimed is:

1. A semiconductor circuit comprising:
a DLL circuit for generating and outputting an output clock signal obtained by delaying an external clock signal that has been input thereto;
a change-in-duty detection circuit, activation and deactivation of which is controlled based upon a control signal, for comparing duty of a clock signal that has been generated based upon the output clock signal and a preset duty and outputting result of the comparison as a change-in-duty signal; and
a duty determination circuit for outputting the control signal for deactivating said change-in-duty detection circuit when the change-in-duty signal indicates that the duty of the output clock signal is in the vicinity of a target value, which is the preset duty, and outputting the control signal for activating said change-in-duty detection circuit when the change-in-duty signal indicates that the duty of the output clock signal is not in the vicinity of the target value, which is the preset duty.

2. The circuit according to claim 1, wherein said duty determination circuit outputs the signal for activating said change-in-duty detection circuit when the change-in-duty signal indicates either large or small in common at a plurality of different timings, and outputs the signal for deactivating the change-in-duty detection circuit when the change-in-duty signal is different at each of a plurality of different timings.

3. The circuit according to claim 1, wherein said DLL circuit outputs the output clock signal by adjusting the temporal position of one edge of the generated output clock signal in accordance with whether this one edge of the output clock signal temporally leads or lags behind one edge of the external clock signal, and adjusting the temporal position of another edge of the output clock signal in accordance with whether this other edge of the output clock signal temporally leads or lags behind another edge of the external clock signal.

4. The circuit according to claim 2, wherein said DLL circuit outputs the output clock signal by adjusting the temporal position of one edge of the generated output clock signal in accordance with whether this one edge of the output clock signal temporally leads or lags behind one edge of the external clock signal, and adjusting the temporal position of another edge of the output clock signal in accordance with whether this other edge of the output clock signal temporally leads or lags behind another edge of the external clock signal.

5. The circuit according to claim 3, further comprising a selection circuit which, in order to adjust the temporal position of the one edge of the output clock signal, selects result of a phase comparison between the external clock signal and the output clock signal in a case where the control signal indicates deactivation of the change-in-duty detection circuit, selects the change-in-duty signal in a case where the control signal indicates activation of the change-in-duty detection circuit, and supplies the selected item to the DLL circuit as information for adjusting the temporal position of the other edge.

6. The circuit according to claim 2, wherein the plurality of different timings are first and second timings, and said circuit further comprises a timing generating circuit for generating timing signals relating to the first and second timings from the external clock signal and outputting these timing signals to said duty determination circuit.

7. The circuit according to claim 6, wherein said duty determination circuit includes:
a first latch circuit for latching the change-in-duty signal at the first timing;
a second latch circuit for latching the change-in-duty signal at the second timing; and
an exclusive-OR gate, to which outputs of respective ones of said first and second latch circuits are input, for taking the exclusive-OR of the outputs of said first and second latch circuits accepted at the first and second timings and outputting the exclusive-OR as the control signal.
